(19) United States
(12) Patent Application Publication
(10) Pub. No.: US 2025/0180956 A1
(43) Pub. Date: Jun. 5, 2025

(54) DISPLAY PANEL AND MANUFACTURING METHOD THEREFOR, AND DISPLAY DEVICE

(71) Applicant: BOE Technology Group Co., Ltd., Beijing (CN)

(72) Inventors: Liwen DONG, Beijing (CN); Changhan HSIEH, Beijing (CN); Dongfei HOU, Beijing (CN); Feng ZHANG, Beijing (CN); Zhao CUI, Beijing (CN); Detian MENG, Beijing (CN); Zhijun LV, Beijing (CN); Wenqu LIU, Beijing (CN); Yuqiao LI, Beijing (CN)

(73) Assignee: BOE Technology Group Co., Ltd., Beijing (CN)

(21) Appl. No.: 19/051,229

(22) Filed: Feb. 12, 2025

Related U.S. Application Data
(63) Continuation of application No. PCT/CN2023/073072, filed on Jan. 19, 2023.

(51) Int. Cl. G02F 1/1368; G02F 1/1362; H10K 10/46; H10K 77/10

(52) U.S. Cl. CPC G02F 1/1368; G02F 1/136209; G02F 1/136222; H10K 10/462; H10K 77/111

(57) ABSTRACT

A display panel includes an array substrate. The array substrate includes: a first flexible substrate; a planarization layer disposed on the first flexible substrate and provided with a groove; a source-drain electrode portion disposed in the groove, a surface of the source-drain electrode portion away from the first flexible substrate being flush with a surface of the planarization layer; an organic semiconductor portion disposed on a side of the source-drain electrode portion and the planarization layer away from the first flexible substrate; a gate insulating portion disposed on a side of the organic semiconductor portion away from the first flexible substrate; and a first gate disposed on a side of the gate insulating portion away from the first flexible substrate.

### CROSS-REFERENCES TO RELATED APPLICATION

This disclosure is a Continuation Application of International Application No. PCT/CN2023/073072, filed on Jan. 19, 2023 and entitled “Display Panel and Manufacturing Method Therefor, and Display Device”, the entire content of which is incorporated herein by reference in its entirety.

### TECHNICAL FIELD

This disclosure relates to the field of display technology and, more particularly, to a display panel and a manufacturing method therefor, and a display device.

### BACKGROUND

At present, OLEDs are widely used as flexible display substrates. To achieve flexible display of LCDs, organic thin film transistors are typically used to switch and drive pixels in LCDs.

In an existing organic thin film transistor, there is a step difference between an active layer and a source-drain electrode portion, which may easily lead to gaps and cracks. Additionally, attachment of the active layer to a sidewall of the source-drain electrode portion may generate lateral current, resulting in a high leakage current (Ioff) of the thin film transistor in an off state.

It should be noted that that information disclosed in the Background is only used to acquire a better understanding of the background of this disclosure and therefore may include information that does not constitute the related art already known to those skilled in the art.

### SUMMARY

An objective of this disclosure is to overcome shortcomings in the related art, and thus provide a display panel and a display device.

According to an aspect of this disclosure, there is provided a display panel, including an array substrate. The array substrate includes: a first flexible substrate, a planarization layer, a source-drain electrode portion, an organic semiconductor portion, a gate insulating portion, and a first gate. The planarization layer is disposed on the first flexible substrate and provided with a groove. The source-drain electrode portion is disposed in the groove, a surface of the source-drain electrode portion away from the first flexible substrate being flush with a surface of the planarization layer. The organic semiconductor portion is disposed on a side of the source-drain electrode portion and the planarization layer away from the first flexible substrate. The gate insulating portion is disposed on a side of the organic semiconductor portion away from the first flexible substrate. The first gate is disposed on a side of the gate insulating portion away from the first flexible substrate.

In an embodiment of this disclosure, an orthographic projection of the organic semiconductor portion on the first flexible substrate covers an orthographic projection of the source-drain electrode portion on the first flexible substrate.

In an embodiment of this disclosure, the planarization layer includes a first planarization sub-layer and a second planarization sub-layer; the first planarization sub-layer is disposed on the first flexible substrate; the second planarization sub-layer is disposed on a side of the first planarization sub-layer away from the first flexible substrate; and the groove is located on the second planarization sub-layer.

In an embodiment of this disclosure, the source-drain electrode portion includes a buffer layer, a low-resistance layer, and a high work function layer that are arranged in a stacked manner.

In an embodiment of this disclosure, the buffer layer is made of Mo, Mo alloy, Ti, ITO, or IZO; the low-resistance layer is made of Cu, Al, or Ag; and the high work function layer is made of a self-assembled monolayer of Ag, ITO, surface-oxidized Mo, surface-oxidized Mo alloy, TiN, Au, Pt, or Pd.

In an embodiment of this disclosure, the source-drain electrode portion is made of a self-assembled monolayer of Ag, ITO, surface-oxidized Mo, surface-oxidized Mo alloy, TiN, Au, Pt, or Pd.

In an embodiment of this disclosure, the array substrate further includes: a passivation layer disposed on a side of the planarization layer away from the first flexible substrate, and covering the first gate, the organic semiconductor portion, and the planarization layer; and a second gate disposed on a side of the passivation layer away from the first flexible substrate, and connected to the first gate through a via hole in the passivation layer.

In an embodiment of this disclosure, the display panel further includes a second conductive portion, and the second conductive portion is disposed between a first adapting portion and a first conductive portion and is disposed on a same layer as the source-drain electrode portion.

In an embodiment of this disclosure, the array substrate further includes: a pixel electrode layer disposed between the source-drain electrode portion and the organic semiconductor portion; and a common electrode layer disposed on the side of the passivation layer away from the first flexible substrate.

In an embodiment of this disclosure, wherein the common electrode layer covers a surface and a side of the second gate.

In an embodiment of this disclosure, the array substate further includes a light-shielding layer disposed on a side of the organic semiconductor portion close to the first flexible substrate, and the light-shielding layer overlaps with at least a part of a channel region of the organic semiconductor portion.

In an embodiment of this disclosure, the display panel further includes a color film substrate, and the color film substrate includes: a second flexible substrate, a third planarization sub-layer, a black matrix layer, a color film layer, a protective layer, and a spacer. The third planarization sub-layer is disposed on a side of the second flexible substrate close to the first flexible substrate. The black matrix layer is disposed on a side of the third planarization sub-layer away from the second flexible substrate and provided with an opening. The color film layer includes at least three filter units of different colors, each filter unit being separately disposed within the opening. The protective layer is disposed on a side of the color film layer and the black matrix layer away from the second flexible substrate, and covers the third planarization layer. The spacer is disposed on a side of the protective layer away from the second flexible substrate.

According to another aspect of this disclosure, there is provided a manufacturing method for a display panel, including:
providing a first flexible substrate;
forming a planarization layer and a source-drain electrode portion on the first flexible substrate, to allow a surface of the source-drain electrode portion away from the first flexible substrate to be flush with a surface of the planarization layer away from the first flexible substrate; and
forming an organic semiconductor portion, a gate insulating portion, and a first gate sequentially stacked on the source-drain electrode portion and the planarization layer.

In an embodiment of this disclosure, forming the planarization layer and the source-drain electrode portion on the first flexible substrate to allow the surface of the source-drain electrode portion away from the first flexible substrate to be flush with the surface of the planarization layer away from the first flexible substrate, includes:
coating a first planarization sub-layer on the first flexible substrate;
depositing a source-drain metal layer on the first planarization sub-layer, and patterning the source-drain metal layer to form the source-drain electrode portion;
coating a second planarization sub-layer on the source-drain electrode portion, the second planarization sub-layer covering the source-drain electrode portion and the first planarization sub-layer; and
ashing the second planarization sub-layer, and stopping ashing when the surface of the source-drain electrode portion away from the first flexible substrate is flush with a surface of the second planarization sub-layer away from the first flexible substrate.

In an embodiment of this disclosure, forming the planarization layer and the source-drain electrode portion on the first flexible substrate to allow the surface of the source-drain electrode portion away from the first flexible substrate to be flush with the surface of the planarization layer away from the first flexible substrate, includes:
coating the planarization layer on the first flexible substrate;
forming a first photoresist layer on the planarization layer, and patterning the first photoresist layer to form a second groove exposing the planarization layer;
ashing the planarization layer in the second groove by using the patterned first photoresist layer as a mask, to form a first groove, wherein an orthographic projection of the first groove on the first flexible substrate overlaps with an orthographic projection of the second groove on the first flexible substrate;
depositing a source-drain metal layer, wherein the source-drain metal layer breaks at an edge of the patterned first photoresist layer that is thinned, to be divided into the source-drain electrode portion formed in the first groove and a to-be-etched portion formed between adjacent second grooves; and
peeling off the patterned first photoresist layer, removing the to-be-etched portion, and retaining the source-drain electrode portion, to allow the surface of the source-drain electrode portion to be flush with the surface of the planarization layer.

In an embodiment of this disclosure, forming the planarization layer and the source-drain electrode portion on the first flexible substrate to allow the surface of the source-drain electrode portion away from the first flexible substrate to be flush with the surface of the planarization layer away from the first flexible substrate, includes:
coating the planarization layer on the first flexible substrate;
forming a second photoresist layer on the planarization layer, and patterning the second photoresist layer to form a third groove exposing the planarization layer;
ashing the planarization layer and the patterned second photoresist layer by using the patterned second photoresist layer as a mask, to form a first groove on the planarization layer while removing the patterned second photoresist layer;
depositing a source-drain metal layer on the ashed planarization layer, to allow a surface, away from the first flexible substrate, of a part of the source-drain metal layer in the first groove to be flush with the surface of the planarization layer away from the first flexible substrate;
forming a patterned third photoresist layer on the source-drain metal layer, wherein an orthographic projection of the patterned third photoresist layer on the planarization layer covers the first groove;
removing a part of the source-drain metal layer between adjacent first grooves by using the patterned third photoresist layer as a mask, to form the source-drain electrode portion;
and peeling off the patterned third photoresist layer on the source-drain electrode portion.

In an embodiment of this disclosure, forming the organic semiconductor portion, the gate insulating portion, and the first gate sequentially stacked on the source-drain electrode portion and the planarization layer, includes:
forming an organic semiconductor layer, a gate insulating layer, and a first gate layer sequentially stacked on the planarization layer;
forming a patterned fourth photoresist layer on the first gate layer;
etching the first gate layer by using the patterned fourth photoresist layer as a mask, to form the first gate, wherein an etching solution selected for the first gate layer is a material non-corrosive to the source-drain electrode portion;
forming a patterned fifth photoresist layer on the organic semiconductor layer, wherein the patterned fifth photoresist layer covers the first gate;
etching the gate insulating layer and the organic semiconductor layer by using the patterned fifth photoresist layer as a mask, to form the gate insulating portion and the organic semiconductor portion; and
peeling off the patterned fifth photoresist layer on a side of the organic semiconductor portion away from the first flexible substrate.

In an embodiment of this disclosure, the manufacturing method further includes:
bonding the array substrate to a first glass substrate by using a first double-sided adhesive, one side of the first double-sided adhesive being a thermal debonding adhesive while another side of the first double-sided adhesive being a UV debonding adhesive; and bonding the color film substrate to a second glass substrate by using a second double-sided adhesive, both sides of the second double-sided adhesive being UV debonding adhesives;
aligning the color film substrate with the array substrate;
heating the display panel, and debonding the thermal debonding adhesive between the array substrate and the first glass substrate, to peel off the array substrate from the first glass substrate; and
irradiating the second glass substrate with UV light, and debonding the UV debonding adhesive between the second glass substrate and the color film substrate, to peel off the color film substrate from the second glass substrate.

According to yet another aspect of this disclosure, there is provided a display device, including the display panel according to the above aspect of this disclosure.

It should be understood that the foregoing general description and the following detailed description are merely exemplary and explanatory, and are not intended to limit this disclosure.

### BRIEF DESCRIPTION OF THE DRAWINGS

The accompanying drawings, which are incorporated into and constitute a part of this specification, illustrate embodiments consistent with this disclosure and, together with the description, serve to explain the principles of this disclosure. It is evident that the drawings in the following description are only some embodiments of this disclosure. For those skilled in the art, other drawings may be derived from these drawings without creative effort.

FIG. 1 is a schematic sectional view of a display panel according to an embodiment of this disclosure.

FIG. 2 is a schematic sectional view of an array substrate according to an embodiment of this disclosure.

FIG. 3 is a schematic sectional view of an array substrate according to an embodiment of this disclosure.

FIG. 4 is a flowchart of a manufacturing method for a display panel according to an embodiment of this disclosure.

FIG. 5 is a schematic sectional view of a first planarization sub-layer according to an embodiment of this disclosure.

FIG. 6 is a schematic sectional view after a patterned source-drain metal layer is formed on a first planarization sub-layer according to an embodiment of this disclosure.

FIG. 7 is a schematic sectional view after a second planarization sub-layer is coated on a patterned source-drain metal layer according to an embodiment of this disclosure.

FIG. 8 is a schematic sectional view after a second planarization sub-layer is ashed according to an embodiment of this disclosure.

FIG. 9 is a schematic sectional view of a planarization layer according to an embodiment of this disclosure.

FIG. 10 is a schematic sectional view after a first photoresist layer is formed on a planarization layer according to an embodiment of this disclosure.

FIG. 11 is a schematic sectional view after a planarization layer in a second groove is ashed according to an embodiment of this disclosure.

FIG. 12 is a schematic sectional view after a source-drain metal layer is deposited on a planarization layer and a first photoresist layer according to an embodiment of this disclosure.

FIG. 13 is a schematic sectional view showing that a patterned second photoresist layer is formed on a planarization layer according to an embodiment of this disclosure.

FIG. 14 is a schematic sectional view showing that a planarization layer and a patterned second photoresist layer are ashed according to an embodiment of this disclosure.

FIG. 15 is a schematic sectional view showing that a source-drain metal layer is deposited on an ashed planarization layer according to an embodiment of this disclosure.

FIG. 16 is a schematic sectional view showing that a patterned third photoresist layer is formed on a source-drain metal layer according to an embodiment of this disclosure.

FIG. 17 is a schematic sectional view showing that a part of a source-drain metal layer between adjacent first grooves is removed according to an embodiment of this disclosure.

FIG. 18 is a schematic sectional view showing that an organic semiconductor layer, a gate insulating layer, and a first gate layer sequentially stacked are formed on a planarization layer according to an embodiment of this disclosure.

FIG. 19 is a schematic sectional view of an organic semiconductor layer, a gate insulating layer, and a first gate layer sequentially stacked are formed on a planarization layer according to an embodiment of this disclosure.

FIG. 20 is a schematic sectional view after a patterned fourth photoresist layer is formed on a first gate layer according to an embodiment of this disclosure.

FIG. 21 is a schematic sectional view after a first gate layer is etched according to an embodiment of this disclosure.

FIG. 22 is a schematic sectional view after a patterned fifth photoresist layer is formed on an organic semiconductor layer according to an embodiment of this disclosure.

FIG. 23 is a schematic sectional view showing that the gate insulating layer and the organic semiconductor layer are etched according to an embodiment of this disclosure.

FIG. 24 is a schematic sectional view after a fifth photoresist layer is peeled off according to an embodiment of this disclosure.

FIG. 25 is a schematic sectional view of a first double-sided adhesive and a second double-sided adhesive according to an embodiment of this disclosure.

### REFERENCE NUMERALS

1—array substrate; 11—first flexible substrate; 12—planarization layer; 121—first planarization sub-layer; 1211—first opening; 122—second planarization sub-layer; 123—first groove; 13—source-drain metal layer; 131—to-be-etched portion; 14—gate insulating layer; 15—organic semiconductor layer; 16—first gate layer; 17—passivation layer; 18—light-shielding layer; 101—organic thin film transistor; 1011—source-drain electrode portion; 1012—gate insulating portion; 1013—organic semiconductor portion; 1014—first gate; 102—second gate; 103—common electrode layer; 104—pixel electrode layer; 2—liquid crystal layer; 3—color film substrate; 31—second flexible substrate; 32—third planarization sub-layer; 33—black matrix layer; 34—color film layer; 341—red filter unit; 342—green filter unit; 343—blue filter unit; 35—protective layer; 36—spacer; 4—first photoresist layer; 41—second groove; 5—second photoresist layer; 51—third groove; 6—third photoresist layer; 7—fourth photoresist layer; 8—fifth photoresist layer; 91—first glass substrate; 92—second glass substrate; 93—first double-sided adhesive; 94—second double-sided adhesive; 95—double-sided adhesive support; 96—thermal debonding adhesive; 97—UV debonding adhesive.

### DETAILED DESCRIPTION

Exemplary embodiments will be now described more fully with reference to the accompanying drawings. However, the exemplary embodiments can be embodied in a variety of forms and should not be construed as limiting the embodiments set forth herein. Instead, these embodiments are provided so that this disclosure will be thorough and complete, and the concepts of the exemplary embodiments will be fully given to those skilled in the art. Same reference numbers denote the same or similar structures in the figures, and thus the detailed description thereof will be omitted. In addition, the drawings are merely schematic illustrations of this disclosure, and are not necessarily drawn to scale.

Although terms having opposite meanings such as “up” and “down” are used herein to describe the relationship of one component relative to another component, such terms are used herein only for the sake of convenience, for example, “in the direction illustrated in the figure”. It can be understood that if a device denoted in the drawings is turned upside down, a component described as “above” something will become a component described as “under” something. When a structure is described as “above” another structure, it probably means that the structure is integrally formed on another structure, or, the structure is “directly” disposed on another structure, or, the structure is “indirectly” disposed on another structure through a further structure.

Words such as “one,” “an/a,” “the” and “said” are used herein to indicate the presence of one or more elements/component parts/and others. Terms “including” and “having” have an inclusive meaning which means that there may be additional elements/component parts/and others in addition to the listed elements/component parts/and others. Terms “first,” “second” and “third” are used herein only as markers, and they do not limit the number of objects modified after them.

A thin film transistor (TFT) is a core component of a display device, as each pixel in the display device relies on the TFT for switching and driving. Depending on different semiconductor material of an active layer in the TFT, traditional TFT mainly includes an amorphous silicon TFT, a polycrystalline silicon TFT, and an oxide TFT. In recent years, flexible display technology has gained significant popularity among consumers. To achieve flexible display in flexible LCDs, organic thin film transistors are typically used to switch and drive pixels in the LCDs.

To maintain the stability of the process and yield, a bottom-contact structure process is currently widely used to fabricate the organic thin film transistors. The formation process of the bottom-contact structure involves first depositing and patterning a source-drain electrode portion, followed by depositing an organic semiconductor layer on the source-drain electrode portion. However, when the bottom-contact structure process is used to fabricate the organic thin film transistors, the organic semiconductor layer deposited above the source-drain electrode portion may exhibit height variations due to changes in a thickness of the source-drain electrode portion, especially at an edge of the source-drain electrode portion. This may easily lead to voids and fractures in the organic semiconductor layer, that is, imposing higher requirements on the material, thickness, and profile of the source-drain electrode portion, and in turn limit the improvement of conductivity of the source-drain electrode portion.

Additionally, attachment of the organic semiconductor layer to a sidewall of the bottom-contact structure may generate lateral currents, resulting in a high leakage current (Ioff) of the thin film transistor in an off state.

In view of this, this disclosure provides a display panel. As shown in the figures, the display panel includes an array substrate 1. The array substrate 1 includes a first flexible substrate 11, a planarization layer 12, a source-drain electrode portion 1011, an organic semiconductor portion 1013, a gate insulating portion 1012, and a first gate 1014. The planarization layer 12 is disposed on the first flexible substrate 11. The planarization layer 12 is provided with a groove. The source-drain electrode portion 1011 is disposed in the groove. A side of the source-drain electrode portion 1011 away from the first flexible substrate 11 is flush with a surface of the planarization layer 12. The organic semiconductor portion 1013 is disposed on the side of the source-drain electrode portion 1011 and the planarization layer 12 away from the first flexible substrate 11. The gate insulating portion 1012 is disposed on a side of the organic semiconductor portion 1013 away from the first flexible substrate 11. The first gate 1014 is disposed on a side of the gate insulating portion 1012 away from the first flexible substrate 11.

In the display panel, the source-drain electrode portion 1011 is embedded into the planarization layer 12, and a surface of the source-drain electrode portion 1011 away from the first flexible substrate 11 is flush with the surface of the planarization layer 12. This may eliminate step difference between the organic semiconductor portion 1013 and the source-drain electrode portion 1011; when the organic semiconductor portion 1013 is formed on the source-drain electrode portion 1011, avoid issues such as fractures and voids, and also prevent the contact between the organic semiconductor portion 1013 and the sidewall of the source-drain electrode portion 1011, thereby solving a problem of the excessive leakage currents (Ioff) in the off state of the thin film transistor.

Hereinafter, the display panel according to this disclosure will be described in detail with reference to specific embodiments.

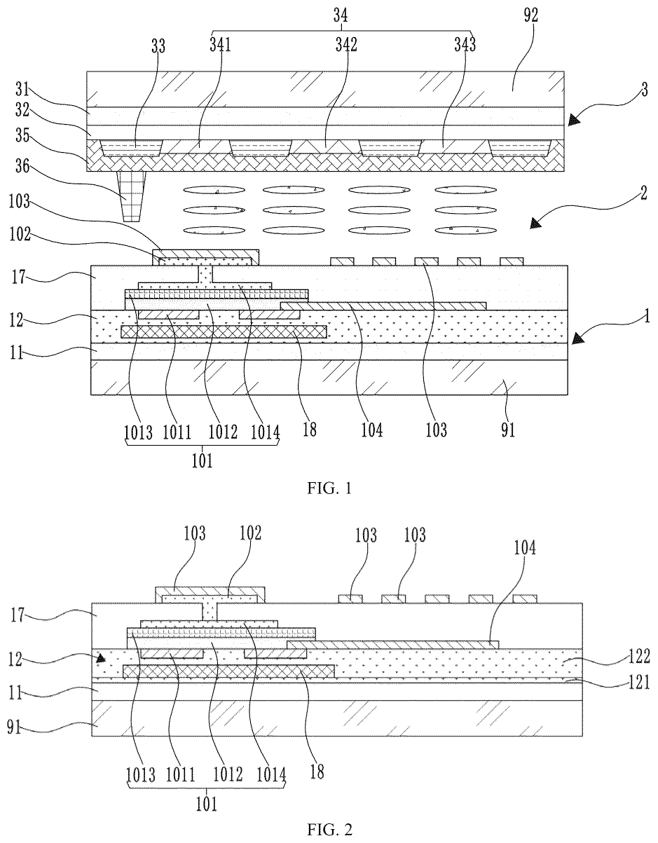

As shown in FIG. 1 and FIG. 2, the display panel includes an array substrate 1, a liquid crystal layer 2, and a color film substrate 3. The array substrate 1 is aligned with the color film substrate 3. The liquid crystal layer 2 is located between the array substrate 1 and the color film substrate 3. The color film substrate 3 is provided with support parts that are cone-shaped structures. A smaller end of each support part abuts against the array substrate 1, and the heights of all support parts are the same.

The array substrate 1 includes a first flexible substrate 11 and a planarization layer 12. The planarization layer 12 includes a first planarization sub-layer 121, which is disposed on the first flexible substrate 11. The first flexible substrate 11 is made of triacetyl cellulose (TAC), which minimizes phase retardation (Retardation). Since triacetyl cellulose has poor water and oxygen barrier properties, the first planarization sub-layer 121 is coated on the first flexible substrate 11. The material of the first planarization sub-layer 121 may be an epoxy resin material, such as SU-8 adhesive.

The array substrate 1 further includes a second planarization sub-layer 122 and an organic thin film transistor 101. The second planarization sub-layer 122 is disposed on a side of the first planarization sub-layer 121 away from the first flexible substrate 11, and the second planarization sub-layer 122 is provided with a groove. The organic thin film transistor 101 includes a source-drain electrode portion 1011, an organic semiconductor portion 1013, a gate insulating portion 1012, and a first gate 1014. The source-drain electrode portion 1011 is disposed in the groove. The side of the source-drain electrode portion 1011 away from the first flexible substrate 11 is flush with the surface of the planarization layer 12. The organic semiconductor portion 1013 is disposed on the source-drain electrode portion 1011 and the planarization layer 12. The gate insulating portion 1012 is disposed on a side of the organic semiconductor portion 1013 away from the first flexible substrate 11. An orthographic projection of the gate insulating portion 1012 on the first flexible substrate 11 overlaps with an orthographic projection of the organic semiconductor portion 1013 on the first flexible substrate 11. The first gate 1014 is disposed on the side of the gate insulating portion 1012 away from the first flexible substrate 11.

Considering a work function, a material of the source-drain electrode portion 1011 may be a self-assembled monolayer of Ag with the work function of 5.86 eV, ITO with the work function of 4.57-4.93 eV, a surface-oxidized Mo with the work function of 5.58 eV, a surface-oxidized Mo alloy with the work function of 5.5 eV, TiN with the work function of 4.49-5.29 eV, Au with the work function of 5.2 eV, Pt with the work function of 5.6 eV, or Pd with the work function of 5.12 eV.

Additionally, considering conductivity, the source-drain electrode portion 1011 may adopt a stacked structure. For example, the source-drain electrode portion 1011 includes a buffer layer (BF), a low-resistance layer (LRF), and a high-work-function layer (HWF) arranged in a stacked manner. In the stacked structure, a middle layer is responsible for reducing line resistance while upper and lower layers protect the middle layer from oxidation or corrosion. The upper layer has strong oxidation resistance and forms a low-resistance ohmic contact with the active layer. The stacked structure exhibits excellent stability.

A material of the buffer layer may be Mo, Mo alloy, Ti, ITO, or IZO. The material of the low-resistance layer may be Cu, Al, Ag, etc. A material of the high work function layer may be a self-assembled monolayer of Ag with the work function of 5.86 eV, ITO with the work function of 4.57-4.93 eV, a surface-oxidized Mo with the work function of 5.58 eV, a surface-oxidized Mo alloy with the work function of 5.5 eV, TiN with the work function of 4.49-5.29 eV, Au with the work function of 5.2 eV, Pt with the work function of 5.6 eV, or Pd with the work function of 5.12 eV. For example, when the source-drain electrode portion 1011 adopts the stacked structure, it may be configured as Mo/Al/Mo and Ti/Al/Ti.

It should be noted that in the stacked structure, a thickness of the three layers depends on designed resistances. Generally, the thickness of the source-drain electrode portion 1011 may be in a range of 500 Å-8000 Å. The thickness of the source-drain electrode portion 1011 in the Mo/Al/Mo structure may be 200/3000/800 Å. The thickness of the source-drain electrode portion 1011 in the Ti/Al/Ti structure may be 500/6500/500 Å. The low-resistance layer requires a sheet resistance of less than 0.2Ω, and Al has a sheet resistance of 0.101Ω. The high work function is a relative concept, compared to LUMO or HOMO energy level of the semiconductor layer. Generally, the closer to the LUMO or HOMO energy level of the semiconductor material, the better it is, and the high work function is typically greater than 5 eV.

When the material of the source-drain metal part is Ag, oxidation is likely to occur. To prevent oxidation of the source-drain metal part, the orthographic projection of the organic semiconductor portion 1013 on the first flexible substrate 11 covers the orthographic projection of the source-drain electrode portion 1011 on the first flexible substrate 11. Certainly, if the source-drain metal part adopts Mo/Al/Mo or Ti/Al/Ti, there is no oxidation issue, and it is not necessary for the organic semiconductor portion 1013 to cover the source-drain metal part. That is, the orthographic projection of the organic semiconductor portion 1013 on the first flexible substrate 11 overlaps with the orthographic projection of the source-drain electrode portion 1011 on the first flexible substrate 11.

The organic semiconductor portion 1013 serves as an active layer of the organic thin film transistor 101. The organic semiconductor portion 1013 may include a channel region and a source region and a drain region, which are two doped regions on both sides of the channel region. The channel region may retain its semiconductor properties while the semiconductor materials in the source and drain regions are partially or entirely conductive. An orthographic projection of the first gate 1014 on the first flexible substrate 11 overlaps with the orthographic projection of the organic semiconductor portion 1013 on the first flexible substrate 11. The orthographic projection of the first gate 1014 on the first flexible substrate 11 at least overlaps with an orthographic projection of the channel region of the organic semiconductor portion 1013 on the first flexible substrate 11. Certainly, the first gate 1014 may also cover part or all of the source and drain regions. The gate insulating portion 1012 covers the channel region, the source region, and the drain region of the organic semiconductor portion 1013. The source-drain electrode portion 1011 typically includes a source electrode and a drain electrode portion, where the source electrode is connected to the source region of the organic semiconductor portion 1013, and the drain electrode portion is connected to the drain region of the organic semiconductor portion 1013.

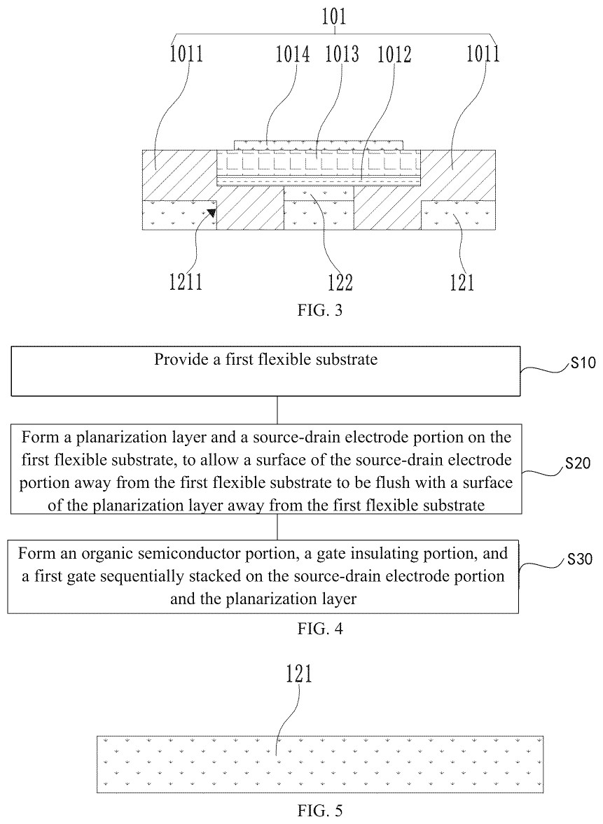

Alternatively, other structures may be adopted to eliminate the step difference between the organic semiconductor portion 1013 and the source-drain electrode portion 1011. As shown in FIG. 3, first openings 1211 may be formed in the first planarization sub-layer 121. A second planarization sub-layer 122 may be disposed between two adjacent first openings 1211. A first portion of the source-drain electrode portion 1011 is provided in the first opening 1211. A side of the first portion away from the first flexible substrate 11 is flush with a side of the second planarization sub-layer 122 away from the first flexible substrate 11. A second portion overlaps with the first planarization sub-layer 121. There is a step difference between the second portion and the first portion. A recessed portion is formed between two adjacent second portions, the side of the first portion away from the first flexible substrate 11, and the second planarization sub-layer 122. The organic semiconductor portion 1013 is disposed in the recessed portion. The side of the organic semiconductor portion 1013 away from the first flexible substrate 11 is flush with the side of the first portion away from the first flexible substrate 11.

The array substrate 1 further includes a passivation layer 17 (PVX) and a second gate 102. The passivation layer 17 is disposed on a side of the planarization layer 12 away from the first flexible substrate 11 and covers the first gate 1014, the organic semiconductor portion 1013, and the planarization layer 12. The second gate 102 is disposed on a side of the passivation layer 17 away from the first flexible substrate 11 and is connected to the first gate 1014 through a via hole in the passivation layer 17. The second gate 102 may serve as a wire, acting as a transmission channel for gate signals of the organic thin film transistor 101 to control the switching of the organic this film transistor 101.

The array substrate 1 further includes a pixel electrode layer 104 and a common electrode layer 103. The pixel electrode layer 104 is disposed between the source-drain electrode portion 1011 and the organic semiconductor portion 1013. The organic semiconductor layer 15 may exhibit a step difference due to the pixel electrode layer 104. However, a carrier has a transmission path from the drain electrode portion, through the channel region of the organic semiconductor layer 15, to the source electrode. Since this position is not part of transmission path of the carrier, it does not affect the stability of the organic thin film transistor.

The common electrode layer 103 is disposed on the side of the passivation layer 17 away from the first flexible substrate 11. Both the pixel electrode layer 104 and the common electrode layer 103 are made of ITO. The common electrode layer 103 covers a surface and sides of the second gate 102. The second gate 102, serving as a wire, is generally made of low-resistance metal materials, such as Mo or Mo/Al/Mo. Since the second gate 102 is prone to oxidation, covering it with ITO having better stability, may prevent oxidation of the second gate 102.

The array substrate 1 may further include a light-shielding layer 18, which is disposed on a side of the organic semiconductor portion 1013 close to the first flexible substrate 11. The light-shielding layer 18 overlaps with at least a part of the channel region of the organic semiconductor portion 1013. The light-shielding layer 18 may block light incident on the organic thin film transistor 101, ensuring the stability of its electrical properties. The material of the light-shielding layer 18 is usually selected from an opaque material, specifically the metal Mo, which is low-cost, easily accessible, and has a mature manufacturing process. The thickness of the light-shielding layer 18 may be set in a range of 1000-3000 Å, and it is generally formed using a wet etching process.

The color film substrate 3 includes a second flexible substrate 31, a third planarization sub-layer 32, a black matrix layer 33, a color film layer 34, a protective layer 35 (over coater, OC), and a spacer 36. The second flexible substrate 31 is arranged opposite to the first flexible substrate 11. The third planarization sub-layer 32 is disposed on a side of the second flexible substrate 31 close to the first flexible substrate 11. The black matrix layer 33 is disposed on a side of the third planarization sub-layer 32 away from the second flexible substrate 31 and is provided with openings. The color film layer 34 includes at least three filter units of different colors, i.e., a red filter unit 341, a green filter unit 342, and a blue filter unit 343. Each filter unit is within the opening. The protective layer 35 is disposed on a side of the color film layer 34 and the black matrix layer 33 away from the second flexible substrate 31, and covers the third planarization sub-layer 32. The spacer 36 is disposed on a side of the protective layer 35 away from the second flexible substrate 31, providing support between the color film substrate 3 and the array substrate 1.

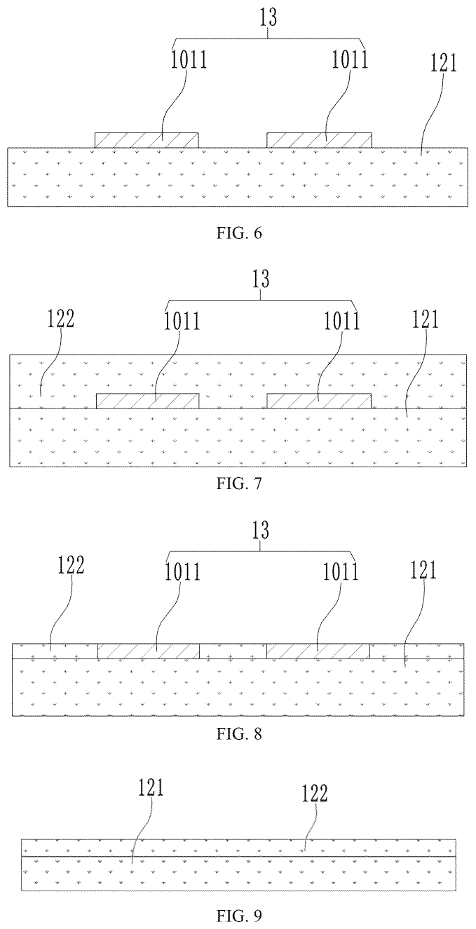

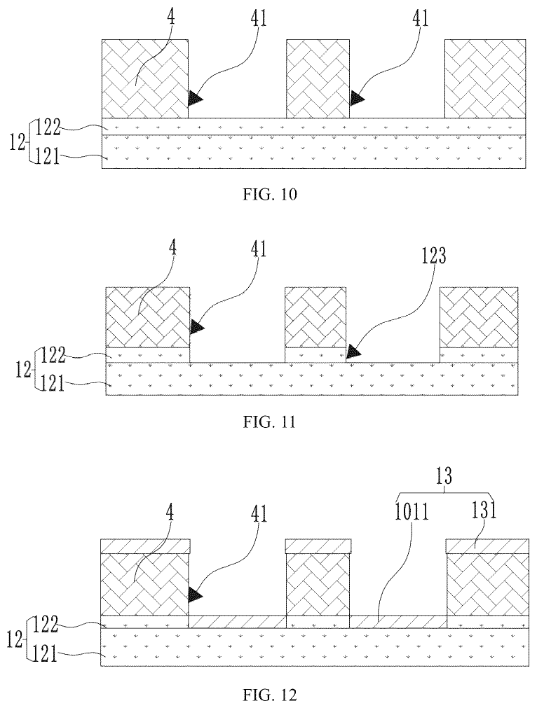

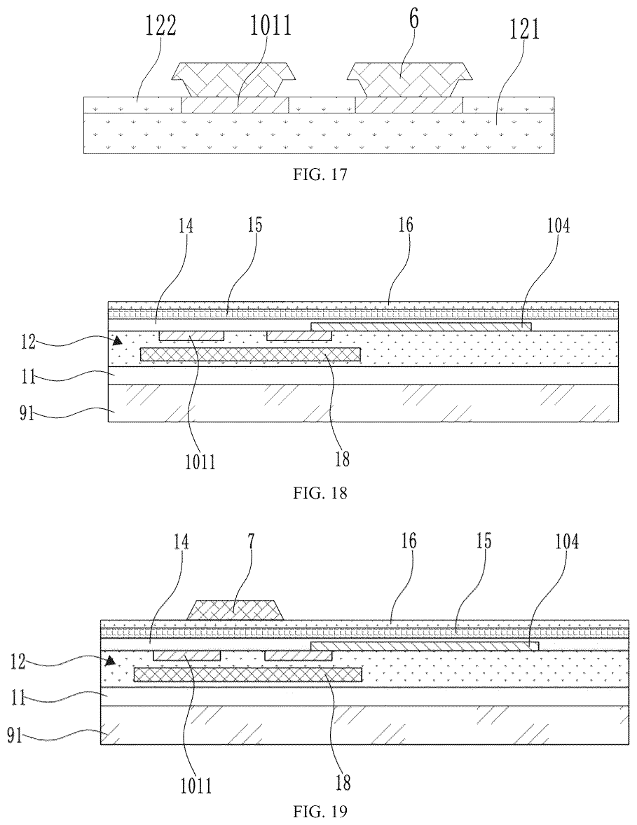

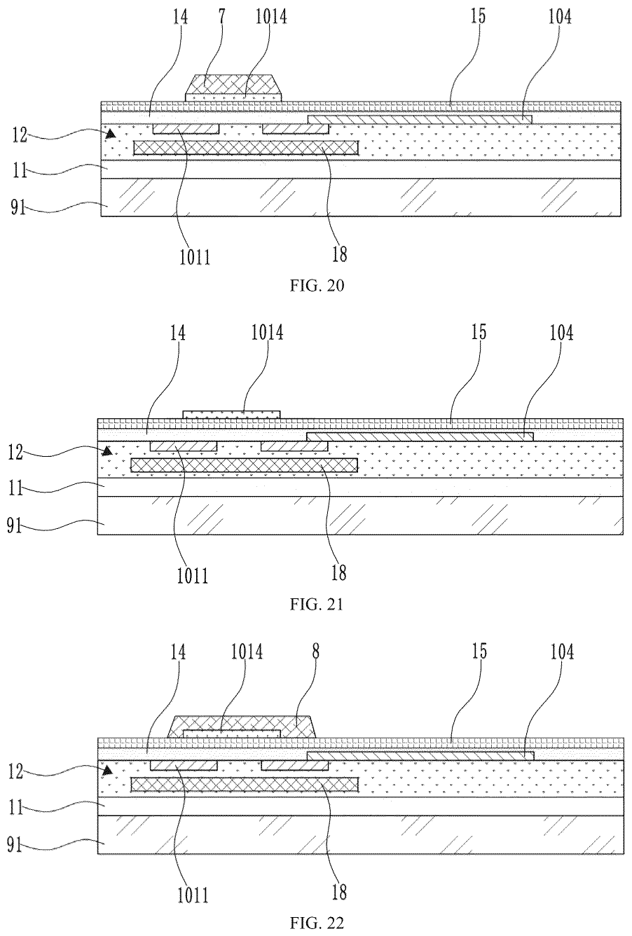

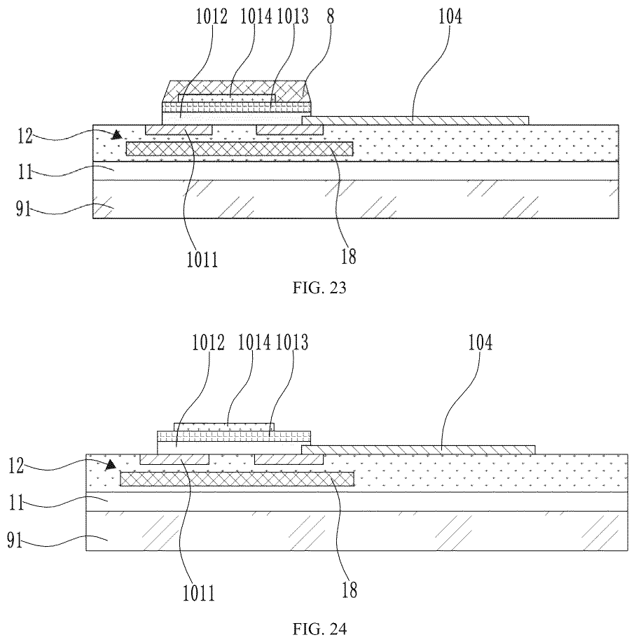

This disclosure provides a manufacturing method for a display panel. As shown in FIG. 4 to FIG. 25, the method includes:
step 10, providing a first flexible substrate 11;
step 20, forming a planarization layer 12 and a source-drain electrode portion 1011 on the first flexible substrate 11, to allow a surface of the source-drain electrode portion 1011 away from the first flexible substrate 11 to be flush with a surface of the planarization layer 12 away from the first flexible substrate 11;
step 30, forming an organic semiconductor portion 1013, a gate insulating portion 1012, and a first gate 1014 sequentially stacked on the source-drain electrode portion 1011 and the planarization layer 12.

In the display panel, the source-drain electrode portion 1011 is embedded into the planarization layer 12, and the side of the source-drain electrode portion 1011 away from the first flexible substrate 11 is flush with a surface of the planarization layer 12. This may eliminate the step difference between the organic semiconductor portion 1013 and the source-drain electrode portion 1011; when the organic semiconductor portion 1013 is formed on the source-drain electrode portion 1011, avoid issues such as fractures and voids, and prevent the contact between the organic semiconductor portion 1013 and the sidewall of the source-drain electrode portion 1011, thereby solving the problem of excessive leakage current (Ioff) in the off state of the thin film transistor.

Hereinafter, the manufacturing method for the display panel according to this disclosure will be described in detail with reference to specific embodiments.

As shown in FIG. 5 to FIG. 8, in this embodiment, step 20 of forming the planarization layer 12 and the source-drain electrode portion 1011 on the first flexible substrate 11 to allow the surface of the source-drain electrode portion 1011 away from the first flexible substrate 11 to be flush with the surface of the planarization layer 12 away from the first flexible substrate 11, may include coating the first planarization sub-layer 121 on the first flexible substrate 11.

Since the first flexible substrate 11 is made of triacetyl cellulose (TAC), which has poor water and oxygen barrier properties, it is necessary to coat the first planarization sub-layer 121 on the surface of the first flexible substrate 11; the material of the first planarization sub-layer 121 may be an epoxy resin material, such as SU-8 adhesive.

A light-shielding layer 18 may also be formed on a side of the first planarization sub-layer 121 away from the first flexible substrate 11; the light-shielding layer 18 may be formed by using a wet etching process; the material and thickness of the light-shielding layer 18 may be referred to the description in the display panel and will not be repeated here.

A source-drain metal layer 13 is deposited on the first planarization sub-layer 121 and the source-drain metal layer 13 is patterned to form the source-drain electrode portion 1011. The material selection and thickness setting of the source-drain metal layer 13 may be referred to the description in the display panel and will not be repeated here.

A second planarization sub-layer 122 is coated on the source-drain electrode portion 1011, and the second planarization sub-layer 122 covers the source-drain electrode portion 1011 and the first planarization sub-layer 121. The purpose of coating the second planarization sub-layer 122 is to planarize the step difference caused by the source-drain electrode portion 1011; the second planarization sub-layer 122 may use an epoxy resin material as the planarization material, such as SU-8 adhesive.

The second planarization sub-layer 122 is ashed, and the ashing is stopped when the side of the source-drain electrode portion 1011 away from the first flexible substrate 11 is flush with the side of the second planarization sub-layer 122 away from the first flexible substrate 11.

It should be noted that ashing the second planarization sub-layer 122 generally involves bombardment with O2 plasma gas. Under the bombardment of O2 plasma gas, the second planarization sub-layer 122 is gradually oxidized and volatilized, thereby becoming thinner.

Referring to FIG. 8 to FIG. 12, in this embodiment, step 20 of forming the planarization layer 12 and the source-drain electrode portion 1011 on the first flexible substrate 11 such that the side of the source-drain electrode portion 1011 away from the first flexible substrate 11 is flush with the side of the planarization layer 12 away from the first flexible substrate 11, may include:
coating the planarization layer 12 on the first flexible substrate 11; herein, the planarization layer 12 may include the first planarization sub-layer 121 and the second planarization sub-layer 122; both the first planarization sub-layer 121 and the second planarization sub-layer 122 may use an epoxy resin material, such as SU-8 adhesive;
forming a first photoresist layer 4 on the planarization layer 12 and patterning the first photoresist layer 4 to form a second groove 41 exposing the planarization layer 12;
coating the first photoresist layer 4 on the second planarization sub-layer 122, and forming a second groove 41 on the first photoresist layer 4 through exposure and development;
a profile of the second groove 41 formed in the first photoresist layer 4 by a peeling-off process is relatively steep, even forming an inverted trapezoidal structure, for the purpose of facilitating spontaneous formation of fractures along the edge of the second groove 41 during subsequent film formation, making it easier to peel off the remaining portion of the first photoresist layer 4 and pattern the subsequent film layers;
ashing the planarization layer 12 in the second groove 41 by using the patterned first photoresist layer 4 as a mask, to form a first groove 123; the first groove 123 may be located on the second planarization sub-layer 122, so that the ashing may be performed on the second planarization layer 12; an orthographic projection of the first groove 123 on the first flexible substrate 11 overlaps with an orthographic projection of the second groove 41 on the first flexible substrate 11, and a depth of the first groove 123 is equal to the thickness of the source-drain electrode portion 1011; the ashing involves bombarding the planarization layer 12 with the O2 plasma gas, which also may thin the patterned first photoresist layer 4 during this process;
depositing the source-drain metal layer 13, which is broken at an edge of the patterned first photoresist layer 4 that has been thinned, to be divided into a to-be-etched portion 131 and the source-drain electrode portion 1011. The source-drain electrode portion 1011 is formed in the first groove 123, and the to-be-etched portion 131 is formed between adjacent second grooves 41;
peeling off the patterned first photoresist layer 4, removing the second portion of the source-drain metal layer 13, and retaining the second portion of the source-drain metal layer 13 as the source-drain electrode portion 1011; the side of the source-drain electrode portion 1011 away from the first flexible substrate 11 is flush with the side of the planarization layer 12 away from the flexible substrate, to form a structure shown in FIG. 8.

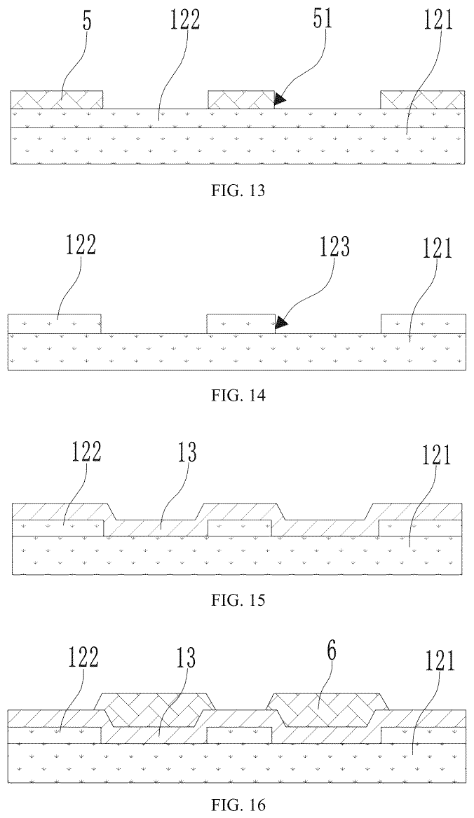

Referring to FIG. 8, FIG. 9, and FIG. 13 to FIG. 17, in this embodiment, forming the planarization layer 12 and the source-drain electrode portion 1011 on the first flexible substrate 11 such that the side of the source-drain electrode portion 1011 away from the first flexible substrate 11 is flush with the side of the planarization layer 12 away from the first flexible substrate 11, includes:
coating the planarization layer 12 on the first flexible substrate 11; as shown in FIG. 8, the planarization layer 12 may include a first planarization sub-layer 121 and a second planarization sub-layer 122; both the first planarization sub-layer 121 and the second planarization sub-layer 122 may use an epoxy resin material, such as SU-8 adhesive;
forming a second photoresist layer 5 on the planarization layer 12 and patterning the second photoresist layer 5 to form a third groove 51 exposing the planarization layer 12; a plurality of third grooves 51 constitute a pattern of the second photoresist layer 5; it should be noted that the pattern of the second photoresist layer 5 is complementary to a pattern of the source-drain electrode portion 1011; the thickness of the second photoresist layer 5 is related to an etching selectivity ratio between the second photoresist layer 5 and the planarization layer 12, and the depth of the first groove 123;
ashing the planarization layer 12 and the patterned second photoresist layer 5 by using the patterned second photoresist layer 5 as a mask; the ashing involves bombarding the planarization layer 12 with the O2 plasma gas, forming the first groove 123 on the planarization layer 12 while removing the patterned second photoresist layer 5; the depth of the first groove 123 is equal to the thickness of the source-drain electrode portion 1011;
depositing the source-drain metal layer 13 on the planarization layer 12 after being ashed, such that a side of a part of the source-drain metal layer 13 in the first groove 123 away from the first flexible substrate is flush with the side of the planarization layer 12 away from the first flexible substrate. Specifically, the side of the part of the source-drain metal layer 13 in the first groove 123 away from the first flexible substrate is flush with the side of the second planarization sub-layer 122 away from the first flexible substrate;
forming a patterned third photoresist layer 6 on the source-drain metal layer 13, an orthographic projection of the patterned third photoresist layer 6 on the planarization layer 12 covers the first groove 123, so as to ensure that the remaining portion of the source-drain metal layer 13 after the etching process exactly fills the first groove 123;
removing the part of the source-drain metal layer 13 between the adjacent first grooves 123 by using the patterned third photoresist layer 6 as a mask, to form the source-drain electrode portion 1011; the side of the source-drain electrode portion 1011 away from the first flexible substrate is flush with the side of the planarization layer 12 away from the first flexible substrate;
peeling off the patterned third photoresist layer 6 on the source-drain electrode portion 1011, to form the structure shown in FIG. 7.

As shown in FIG. 18 to FIG. 24, in the above embodiments, step 30 of forming the organic semiconductor portion 1013, the gate insulating portion 1012, and the first gate 1014 sequentially stacked on the source-drain electrode portion 1011 and the planarization layer 12, includes:
forming the organic semiconductor layer 15, the gate insulating layer 14, and the first gate layer 16 sequentially stacked on the planarization layer 12; as mentioned above, the planarization layer 12 includes a first planarization sub-layer 121 and a second planarization sub-layer 122; typically, an organic semiconductor layer 15 is formed on the side of the second planarization sub-layer 122 away from the first flexible substrate 11; the gate insulating layer 14 is formed on the side of the organic semiconductor layer 15 away from the first flexible substrate 11; and the first gate layer 16 is formed on the side of the gate insulating layer 14 away from the first flexible substrate 11; the organic semiconductor layer 15 is entirely formed on a flat surface, there is not any step difference in the source-drain electrode portion 1011; the organic semiconductor layer 15 only contacts the side of the source-drain electrode portion 1011 away from the first flexible substrate 11 and does not contact the sidewall of the source-drain electrode portion 1011;
forming a patterned fourth photoresist layer 7 on the first gate layer 16; it is possible to coat the fourth photoresist layer 7 on the entire side of the first gate layer 16 away from the first flexible substrate 11, and to expose and develop the third photoresist layer 6 to form the patterned fourth photoresist layer 7;
etching the first gate layer 16 by using the patterned fourth photoresist layer 7 as a mask, to form the first gate 1014. An etching solution selected for the first gate layer 16 is non-corrosive to the source-drain electrode portion 1011;
for the organic thin film transistor 101, to achieve flexibility, the gate insulating layer 14 is typically made of organic materials, which have poor water resistance. For example, when the material of the source-drain electrode portion 1011 is Ag and the material of the first gate layer 16 is Mo, the etching solution for the first gate layer 16 may easily penetrate through the organic semiconductor layer 15 and corrode the Ag under it;
forming a patterned fifth photoresist layer 8 on the organic semiconductor layer 15, the patterned fifth photoresist layer 8 covers the etched first gate 1014; an orthographic projection of the patterned fifth photoresist layer 8 on the first flexible substrate 11 covers an orthographic projection of the source-drain electrode portion 1011 on the first flexible substrate 11;
etching the gate insulating layer 14 and the organic semiconductor layer 15 by using the patterned fifth photoresist layer 8 as a mask, to form the gate insulating portion 1012 and the organic semiconductor portion 1013; the fifth photoresist layer 8 is used to form the gate insulating portion 1012 and the organic semiconductor portion 1013; since an orthographic projection of the fifth photoresist layer 8 on the first flexible substrate 11 covers the orthographic projection of the source-drain electrode portion 1011 on the first flexible substrate 11, the orthographic projection of the organic semiconductor portion 1013 on the first flexible substrate 11 also covers the orthographic projection of the source-drain electrode portion 1011 on the first flexible substrate 11;
peeling off the patterned fourth photoresist layer 7 on the side of the organic semiconductor portion 1013 away from the first flexible substrate.

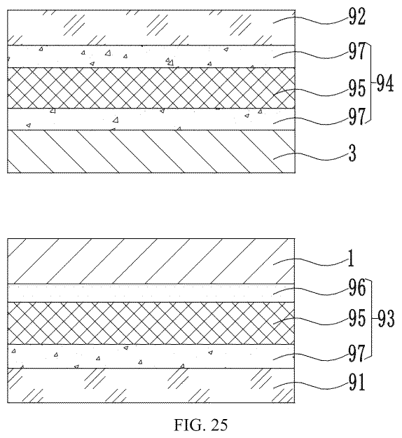

As shown in FIG. 25, a first double-sided adhesive 93 may be used to bond the first flexible substrate 11 to a first glass substrate 91, and a second double-sided adhesive 94 may be used to bond the second flexible substrate 31 to a second glass substrate 92. It should be noted that the first double-sided adhesive 93 includes a double-sided adhesive support 95 and a thermal debonding adhesive 96 and a UV debonding adhesive 97 located on opposite sides of the double-sided adhesive support 95. The second double-sided adhesive 94 includes a double-sided adhesive support 95 and UV debonding adhesives 97 located on opposite sides of the double-sided adhesive support 95.

The method may further include:
bonding the array substrate 1 to the first glass substrate 91 by using the first double-sided adhesive 93, and bonding the color film substrate 3 to the second glass substrate 92 by using the second double-sided adhesive 94;
aligning the color film substrate 3 with the array substrate 1, in which the color film substrate 3 may be laser-cut before aligning, or the color film substrate 3 may be laser-cut after aligning;
heating the display panel, and debonding the thermal debonding adhesive 96 between the array substrate 1 and the first glass substrate 91, to peel off the array substrate 1 from the first glass substrate 91; and
irradiating the second glass substrate 92 with UV light, and debonding the UV debonding adhesive 97 between the second glass substrate 92 and the color film substrate 3, to peel off the color film substrate 3 from the second glass substrate 92.

The array substrate 1 is laser-cut.

It may be understood that the display panel of this disclosure may adopt the first flexible substrate, the second flexible substrate, and the organic thin film transistor, to realize flexible display for LCDs.

this disclosure provides a display device. The display device may include the display panel described in any of the above embodiments. The beneficial effects of the display device may be referred to the beneficial effects of the display panel and will not be repeated here.

It should be noted that the display device includes other necessary components and elements in addition to the display panel. Taking a display as an example, it may include a housing, a circuit board, a power cord, etc. Those skilled in the art may supplement these components according to the specific requirements of the display device, and will not be repeated here.

The display device may be a traditional electronic device, such as a mobile phone, a computer, a television, or a camcorder, or an emerging wearable device, such as VR glasses. These examples will not be listed exhaustively.

Other embodiments of this disclosure will be apparent to those skilled in the art from consideration of the specification and practice of the invention disclosed here. This application is intended to cover any variations, uses, or adaptations of this disclosure following the general principles thereof and including common knowledge or conventional technical means in the art that is not disclosed herein. The specification and embodiments are considered to be merely exemplary, and the true scope of this disclosure is indicated by the appended claims.

What is claimed is:

1. A display panel, comprising an array substrate, wherein the array substrate comprises:
a first flexible substrate;
a planarization layer disposed on the first flexible substrate and provided with a groove;
a source-drain electrode portion disposed in the groove, a surface of the source-drain electrode portion away from the first flexible substrate being flush with a surface of the planarization layer;
an organic semiconductor portion disposed on a side of the source-drain electrode portion and the planarization layer away from the first flexible substrate;
a gate insulating portion disposed on a side of the organic semiconductor portion away from the first flexible substrate; and
a first gate disposed on a side of the gate insulating portion away from the first flexible substrate.

2. The display panel according to claim 1, wherein an orthographic projection of the organic semiconductor portion on the first flexible substrate covers an orthographic projection of the source-drain electrode portion on the first flexible substrate.

3. The display panel according to claim 1, wherein the planarization layer comprises a first planarization sub-layer and a second planarization sub-layer; the first planarization sub-layer is disposed on the first flexible substrate; the second planarization sub-layer is disposed on a side of the first planarization sub-layer away from the first flexible substrate; and the groove is located on the second planarization sub-layer.

4. The display panel according to claim 1, wherein the source-drain electrode portion comprises a buffer layer, a low-resistance layer, and a high work function layer that are arranged in a stacked manner.

5. The display panel according to claim 4, wherein the buffer layer is made of Mo, Mo alloy, Ti, ITO, or IZO; the low-resistance layer is made of Cu, Al, or Ag; and the high work function layer is made of a self-assembled monolayer of Ag, ITO, surface-oxidized Mo, surface-oxidized Mo alloy, TiN, Au, Pt, or Pd.

6. The display panel according to claim 1, wherein the source-drain electrode portion is made of a self-assembled monolayer of Ag, ITO, surface-oxidized Mo, surface-oxidized Mo alloy, TiN, Au, Pt, or Pd.

7. The display panel according to claim 1, wherein the array substrate further comprises:
a passivation layer disposed on a side of the planarization layer away from the first flexible substrate, and covering the first gate, the organic semiconductor portion, and the planarization layer; and
a second gate disposed on a side of the passivation layer away from the first flexible substrate, and connected to the first gate through a via hole in the passivation layer.

8. The display panel according to claim 7, wherein the array substrate further comprises:
a pixel electrode layer disposed between the source-drain electrode portion and the organic semiconductor portion; and
a common electrode layer disposed on the side of the passivation layer away from the first flexible substrate.

9. The display panel according to claim 8, wherein the common electrode layer covers a surface and a side of the second gate.

10. The display panel according to claim 1, wherein the array substate further comprises a light-shielding layer disposed on a side of the organic semiconductor portion close to the first flexible substrate, and the light-shielding layer overlaps with at least a part of a channel region of the organic semiconductor portion.

11. The display panel according to claim 1, further comprising a color film substrate, wherein the color film substrate comprises:
a second flexible substrate;
a third planarization sub-layer disposed on a side of the second flexible substrate close to the first flexible substrate;
a black matrix layer disposed on a side of the third planarization sub-layer away from the second flexible substrate, and provided with an opening;
a color film layer comprising at least three filter units of different colors, each filter unit being separately disposed within the opening;
a protective layer disposed on a side of the color film layer and the black matrix layer away from the second flexible substrate, and covering the third planarization layer; and
a spacer disposed on a side of the protective layer away from the second flexible substrate.

12. A manufacturing method for a display panel, comprising:
providing a first flexible substrate;
forming a planarization layer and a source-drain electrode portion on the first flexible substrate, to allow a surface of the source-drain electrode portion away from the first flexible substrate to be flush with a surface of the planarization layer away from the first flexible substrate; and
forming an organic semiconductor portion, a gate insulating portion, and a first gate sequentially stacked on the source-drain electrode portion and the planarization layer.

13. The manufacturing method for the display panel according to claim 12, wherein forming the planarization layer and the source-drain electrode portion on the first flexible substrate to allow the surface of the source-drain electrode portion away from the first flexible substrate to be flush with the surface of the planarization layer away from the first flexible substrate, comprises:
coating a first planarization sub-layer on the first flexible substrate;
depositing a source-drain metal layer on the first planarization sub-layer, and patterning the source-drain metal layer to form the source-drain electrode portion;
coating a second planarization sub-layer on the source-drain electrode portion, the second planarization sub-layer covering the source-drain electrode portion and the first planarization sub-layer; and
ashing the second planarization sub-layer, and stopping ashing in response to that the surface of the source-drain electrode portion away from the first flexible substrate is flush with a surface of the second planarization sub-layer away from the first flexible substrate.

14. The manufacturing method for the display panel according to claim 12, wherein forming the planarization layer and the source-drain electrode portion on the first flexible substrate to allow the surface of the source-drain electrode portion away from the first flexible substrate to be flush with the surface of the planarization layer away from the first flexible substrate, comprises:
coating the planarization layer on the first flexible substrate;
forming a first photoresist layer on the planarization layer, and patterning the first photoresist layer to form a second groove exposing the planarization layer;
ashing the planarization layer in the second groove by using the patterned first photoresist layer as a mask, to form a first groove, wherein an orthographic projection of the first groove on the first flexible substrate overlaps with an orthographic projection of the second groove on the first flexible substrate;
depositing a source-drain metal layer, wherein the source-drain metal layer breaks at an edge of the patterned first photoresist layer that is thinned, to be divided into the source-drain electrode portion formed in the first groove and a to-be-etched portion formed between adjacent second grooves; and
peeling off the patterned first photoresist layer, removing the to-be-etched portion, and retaining the source-drain electrode portion, to allow the surface of the source-drain electrode portion to be flush with the surface of the planarization layer.

15. The manufacturing method for the display panel according to claim 12, wherein forming the planarization layer and the source-drain electrode portion on the first flexible substrate to allow the surface of the source-drain electrode portion away from the first flexible substrate to be flush with the surface of the planarization layer away from the first flexible substrate, comprises:
coating the planarization layer on the first flexible substrate;
forming a second photoresist layer on the planarization layer, and patterning the second photoresist layer to form a third groove exposing the planarization layer;
ashing the planarization layer and the patterned second photoresist layer by using the patterned second photoresist layer as a mask, to form a first groove on the planarization layer while removing the patterned second photoresist layer;
depositing a source-drain metal layer on the ashed planarization layer, to allow a surface, away from the first flexible substrate, of a part of the source-drain metal layer in the first groove to be flush with the surface of the planarization layer away from the first flexible substrate;
forming a patterned third photoresist layer on the source-drain metal layer, wherein an orthographic projection of the patterned third photoresist layer on the planarization layer covers the first groove;
removing a part of the source-drain metal layer between adjacent first grooves by using the patterned third photoresist layer as a mask, to form the source-drain electrode portion; and
peeling off the patterned third photoresist layer on the source-drain electrode portion.

16. The manufacturing method for the display panel according to claim 12, wherein forming the organic semiconductor portion, the gate insulating portion, and the first gate sequentially stacked on the source-drain electrode portion and the planarization layer, comprises:
forming an organic semiconductor layer, a gate insulating layer, and a first gate layer sequentially stacked on the planarization layer;
forming a patterned fourth photoresist layer on the first gate layer;
etching the first gate layer by using the patterned fourth photoresist layer as a mask, to form the first gate, wherein an etching solution selected for the first gate layer is a material non-corrosive to the source-drain electrode portion;
forming a patterned fifth photoresist layer on the organic semiconductor layer, wherein the patterned fifth photoresist layer covers the first gate;
etching the gate insulating layer and the organic semiconductor layer by using the patterned fifth photoresist layer as a mask, to form the gate insulating portion and the organic semiconductor portion; and
peeling off the patterned fifth photoresist layer on a side of the organic semiconductor portion away from the first flexible substrate.

17. The manufacturing method for the display panel according to claim 12, wherein the display panel comprises an array substrate and a color film substrate; the array substrate comprises: a first flexible substrate, a planarization layer disposed on the first flexible substrate and provided with a groove, a source-drain electrode portion disposed in the groove, a surface of the source-drain electrode portion away from the first flexible substrate being flush with a surface of the planarization layer, an organic semiconductor portion disposed on a side of the source-drain electrode portion and the planarization layer away from the first flexible substrate, a gate insulating portion disposed on a side of the organic semiconductor portion away from the first flexible substrate, and a first gate disposed on a side of the gate insulating portion away from the first flexible substrate; the color film substrate comprises: a second flexible substrate, a third planarization sub-layer disposed on a side of the second flexible substrate close to the first flexible substrate, a black matrix layer disposed on a side of the third planarization sub-layer away from the second flexible substrate, and provided with an opening, a color film layer comprising at least three filter units of different colors, each filter unit being separately disposed within the opening, a protective layer disposed on a side of the color film layer and the black matrix layer away from the second flexible substrate and covering the third planarization layer, and a spacer disposed on a side of the protective layer away from the second flexible substrate,
wherein the manufacturing method further comprises:
bonding the array substrate to a first glass substrate by using a first double-sided adhesive, one side of the first double-sided adhesive being a thermal debonding adhesive while another side of the first double-sided adhesive being a UV debonding adhesive; and bonding the color film substrate to a second glass substrate by using a second double-sided adhesive, both sides of the second double-sided adhesive being UV debonding adhesives;
aligning the color film substrate with the array substrate;
heating the display panel, and debonding the thermal debonding adhesive between the array substrate and the first glass substrate, to peel off the array substrate from the first glass substrate; and
irradiating the second glass substrate with UV light, and debonding the UV debonding adhesive between the second glass substrate and the color film substrate, to peel off the color film substrate from the second glass substrate.

18. A display device, comprising a display panel comprising an array substrate, wherein the array substrate comprises:
a first flexible substrate;
a planarization layer disposed on the first flexible substrate and provided with a groove;
a source-drain electrode portion disposed in the groove, a surface of the source-drain electrode portion away from the first flexible substrate being flush with a surface of the planarization layer;
an organic semiconductor portion disposed on a side of the source-drain electrode portion and the planarization layer away from the first flexible substrate;
a gate insulating portion disposed on a side of the organic semiconductor portion away from the first flexible substrate; and
a first gate disposed on a side of the gate insulating portion away from the first flexible substrate.

19. The display device according to claim 18, wherein an orthographic projection of the organic semiconductor portion on the first flexible substrate covers an orthographic projection of the source-drain electrode portion on the first flexible substrate.

20. The display device according to claim 18, wherein the planarization layer comprises a first planarization sub-layer and a second planarization sub-layer; the first planarization sub-layer is disposed on the first flexible substrate; the second planarization sub-layer is disposed on a side of the first planarization sub-layer away from the first flexible substrate; and the groove is located on the second planarization sub-layer.
